(19) United States
(12) Patent Application Publication
(10) Pub. No.: US 2008/0084238 A1
(43) Pub. Date: Apr. 10, 2008

(54) Latch-type level shift circuit

(75) Inventor: Yu Jui Chang, Hsinhua Township (TW)

Correspondence Address: OLIFF & BERRIDGE, PLC, P.O. BOX 320850, ALEXANDRIA, VA, 22320-4850, US

(73) Assignee: HIMAX TECHNOLOGIES LIMITED, HSINHUA TOWNSHIP (TW)

(21) Appl. No.: 11/543,821

(22) Filed: Oct. 6, 2006

(51) Int. Cl. H03L 5/00

(52) U.S. Cl. 327/333

(57) ABSTRACT

A latch-type level shift circuit comprises a first latch circuit and a second latch circuit. The first latch circuit is powered by an independent reference voltage and receives a differential pair of low voltage signals to generate a differential pair of intermediate signals. The second latch circuit is powered by an internal reference voltage and receives the differential pair of intermediate signals to generate a differential pair of high-voltage output signals. The first latch circuit of the latch-type level shift circuit replaces the inverters used in the conventional level shift circuit, and thus, the capability of changing the state of the latch-type level shift circuit is improved.

### BACKGROUND OF THE INVENTION

1. Field of the Invention

The present invention relates to a level shift circuit, and more particularly, to a latch-type level shift circuit, which is suitable to be used in a source driver of a liquid crystal display (LCD) panel.

2. Description of the Related Art

A level shift circuit is usually utilized for transferring a signal generated by a circuit having a low voltage level to a circuit having a higher voltage level; therefore, the level shift circuit can be applied to diverse contemporary devices requiring a low power supply voltage and multi-power supplies. When the level shift circuit is employed in a source driver of an LCD panel, one of its functions is to transfer a signal with a logic power supply VDDD, e.g., approximately 3.3 volts, or a logic ground VSSD, i.e., 0 volts, to a signal with a driver power supply VDDA, e.g., approximately between 8.0 volts and 13.5 volts, or a driver ground VSSA, i.e., 0 volts, respectively. FIGS. 1(a) and 1(b) show the operation of a conventional level shift circuit 1 used in the source driver of the LCD panel. The conventional level shift circuit 1 comprises high-voltage (HV) PMOS transistors C and D, HV NMOS transistors A and B, and an HV PMOS transistor E. The HV PMOS transistors C and D have sources thereof electrically coupled to the driver power supply VDDA through the HV PMOS transistor E. A gate of the HV PMOS transistor D is electrically connected to a drain of the HV PMOS transistor C. A gate of the HV PMOS transistor C is electrically connected to a drain of the HV PMOS transistor D. The HV NMOS transistors A and B receive input signals INB and IN, respectively, where the input signals IN and INB are complementary. The drains of the HV NMOS transistors A and B are electrically connected to the drains of the HV PMOS transistors C and D, respectively. The sources of the HV NMOS transistors A and B are electrically connected to the driver ground VSSA.

Referring to FIG. 1(a), when an input signal IN in high state with the voltage level of the logic power supply VDDD is applied to the gate of the HV NMOS transistor B, the gate of the HV PMOS transistor C is grounded (i.e., at the driver ground VSSA). Accordingly, the HV NMOS transistor B and the HV PMOS transistor C are in a conductive state and an output signal OUT at a node S1 is in high state with the voltage level of the driver power supply VDDA. However, the gate of the HV NMOS transistor A receives an inverse input signal INB in low state of 0 volts and the gate of the HV PMOS transistor D receives the voltage level of the output signal OUT; and thus, both the HV NMOS transistor A and the HV PMOS transistor D are in a non-conductive state (indicated with a cross mark thereon). Accordingly, the input signal IN in high state with the voltage level of the logic power supply VDDD is transferred to the output signal OUT in high state with the voltage level of the driver power supply VDDA. Referring to FIG. 1(b), when the input signal IN switches from the high state with the voltage level of the logic power supply VDDD to the low state with the voltage level of the logic ground VSSD and is applied to the gate of the HV NMOS transistor B, the HV NMOS transistor B is in a non-conductive state. At the same time, the inverse input signal INB switches from the low state with the voltage level of the logic ground VSSD to the high state with the voltage level of the logic power supply VDDD and is applied at the gate of the NMOS transistor A. Thus, the output signal OUT at the node S1 and the gate of the HV PMOS transistor D are both grounded. Consequently, the HV PMOS transistor D is made conductive and the voltage level at a node S2 is in high state with the voltage level of the driver power supply VDDA to put the HV PMOS transistor C in a non-conductive state. Therefore, both the HV NMOS transistor A and the HV PMOS transistor D are in a conductive state and the output signal OUT at the node S1 is in low state with the voltage level of the driver ground VSSA; both the HV NMOS transistor B and the HV PMOS transistor C are in a non-conductive state (indicated with a cross mark thereon). Accordingly, the input signal IN in low state with the voltage level of the logic ground VSSD (0 volts) is transferred to the output signal OUT in high state with the voltage level of the driver ground VSSA (0 volts).

In the conventional level shift circuit 1 of FIGS. 1(a) and 1(b), the input stage involves HV NMOS transistors. When the conventional level shift circuit 1 is used for low-voltage applications (e.g., the input signal of 1.8 volts), the HV NMOS transistor A cannot switch from “off” (i.e., non-conductive state) to “on” (i.e., conductive state) smoothly. Thus, the conventional level shift circuit 1 cannot change state properly, and may even fail to change state. That is, the capability of switching from “off” to “on” of the HV NMOS transistor A is not reliable that it may take a longer time to complete the switching from “off” to “on.” Therefore, it is possible to turn on the four HV transistors A-D simultaneously in a moment, inducing a DC current flowing through the conventional level shift circuit 1 to the driver ground VSSA. In a general design of level shift circuits inside the source driver, six or eight groups of the four HV transistors A-D 11 are commonly connected to an HV PMOS transistor E providing the driver power supply VDDA. Note that each group of four HV transistors A-D 11 corresponds to a 1-bit data. If the source driver has 384 output channels and each channel contains six bits, there are 386×6 level shift circuits used in the source driver. The circuit layout of these 386×6 level shift circuits contributes a large equivalent resistance. When the DC current flows through the large equivalent resistance, the voltage level of VSSA ramps up from the ground level and thus, the HV NMOS transistor A in some groups of the four HV transistors A-D 11 becomes difficult to be turned on. Accordingly, the conventional level shift circuit 1 is latched with the DC current flowing.

Referring to FIG. 2, which shows the conventional level shift circuit 1 combined with a low-voltage (LV) input stage 2, to solve the issue of changing the state of the conventional level shift circuit 1, the LV input stage 2 having an internal power IR provided by a charge pump (not shown) is connected to the gate of the HV NMOS transistor B of FIG. 1(a) through a third node S3. However, when the input signal DIN in high state is applied, which comes from an external power with a voltage level smaller than that of the internal power IR, an LV PMOS transistor 210 of an inverter 21 cannot turn off completely, and this results in a leakage current. Furthermore, using the design of the charge pump, the upper voltage provided by the internal power IP cannot exceed Hi(DIN)+Vₜ, or a leakage current results from the LV PMOS transistor 210, where Hi(DIN) is the voltage level of the input signal DIN in high state and Vₜ is the threshold voltage of the LV PMOS transistor 210.

### SUMMARY OF THE INVENTION

One objective of the present invention is to provide a latch-type level shift circuit, which replaces the inverters in the conventional level shift circuit with a latch circuit, to sustain a higher internal power without a leakage current and exhibit a high capability of changing state.

Another objective of the present invention is to provide a latch-type level shift circuit, which replaces the inverters in the conventional level shift circuit with a high level controlled level shift circuit, to exhibit no leakage current and a high capability of changing state, and to omit the use of a charge pump circuit.

In order to achieve the above objectives, the present invention discloses a first embodiment of the latch-type level shift circuit, which comprises a first latch circuit and a second latch circuit. The first latch circuit is powered by an independent reference voltage, and receives a differential pair of low-voltage (LV) input signals to generate a differential pair of intermediate signals. The second latch circuit is powered by an internal reference voltage, and receives the differential pair of intermediate signals to generate a differential pair of high-voltage (HV) output signals. The first embodiment of the latch-type level shift circuit further comprises a switch circuit selectively providing the internal reference voltage to the second latch circuit. Also, the first embodiment of the latch-type level shift circuit further comprises a charge pump circuit boosting an external reference voltage that is lower than the internal reference voltage to generate the independent reference voltage.

The latch-type level shift circuit of a second embodiment comprises a first latch circuit, a second latch circuit, and an HV NMOS transistor. The first latch receives a differential pair of LV input signals to generate a differential pair of intermediate signals. The second latch circuit is powered by an internal reference voltage, and receives the differential pair of intermediate signals to generate a differential pair of HV output signals. The HV NMOS transistor has a drain receiving the internal reference voltage, a gate receiving a predetermined limit voltage, and a source powering the first latch circuit, so as to prevent the first latch circuit from HV damages. The second embodiment of the latch-type level shift circuit further comprises an HV switch circuit selectively providing the internal reference voltage to the second latch circuit.

### BRIEF DESCRIPTION OF THE DRAWINGS

The invention will be described according to the appended drawings in which:

FIGS. 1(a) and 1(b) show the operation of a conventional level shift circuit;

FIG. 2 shows a conventional level shift circuit combined with a low-voltage input stage;

FIG. 3 shows a block diagram of the latch-type level shift circuit in accordance with the first embodiment of the present invention;

FIG. 4 shows an embodiment of the first latch circuit used in FIG. 3;

FIG. 5 shows a block diagram of the latch-type level shift circuit in accordance with the second embodiment of the present invention;

FIG. 6 shows an embodiment of the first latch circuit used in FIG. 5.

### DETAILED DESCRIPTION OF THE INVENTION

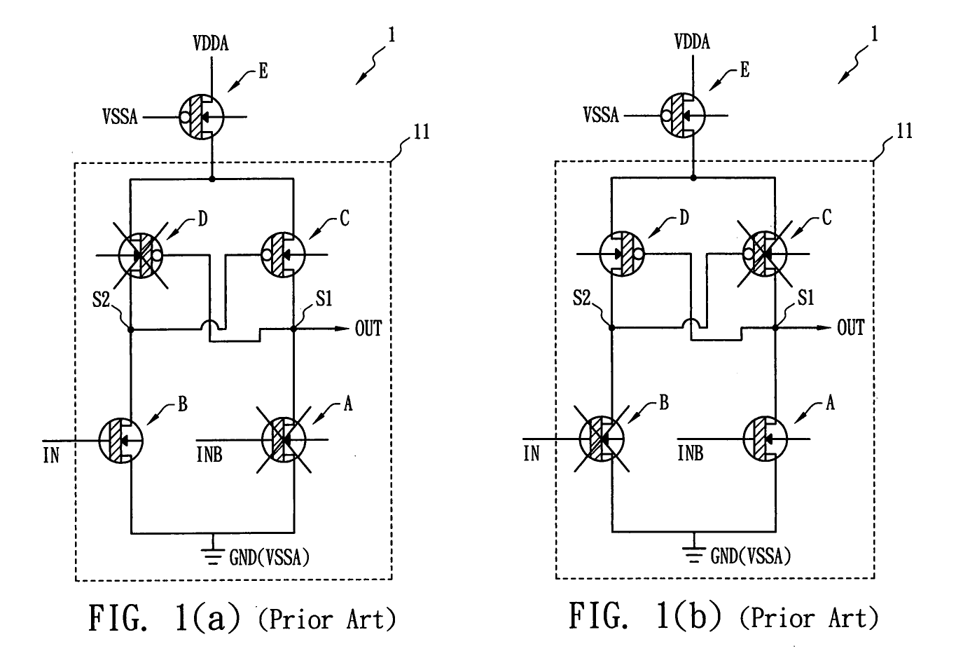

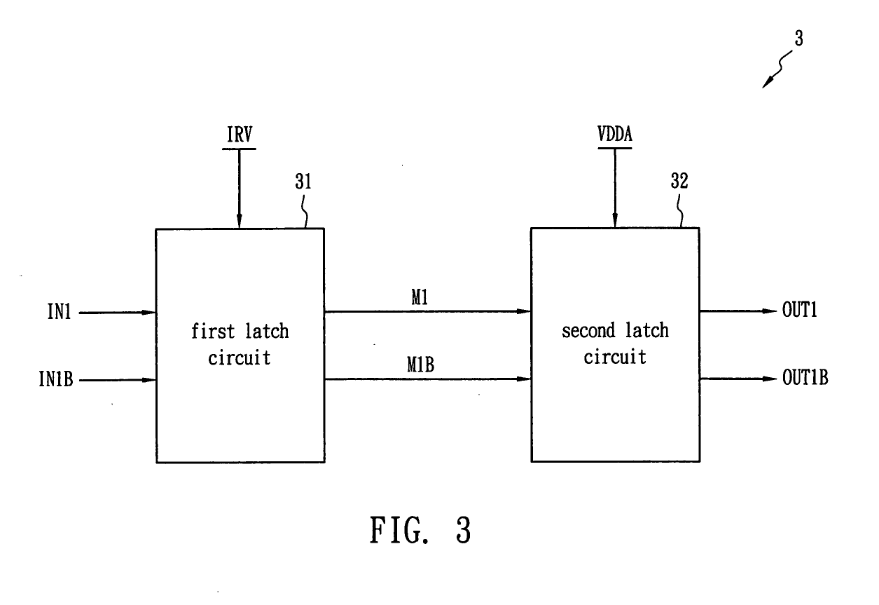

FIG. 3 shows a block diagram of the latch-type level shift circuit 3 in accordance with the first embodiment of the present invention. The latch-type level shift circuit 3 comprises a first latch circuit 31 and a second latch circuit 32. In this embodiment, the second latch circuit 32 is equivalent to the conventional level shift circuit 1 of FIG. 1(a). The first latch circuit 31 is powered by an independent reference voltage IRV, and receives a differential pair of LV input signals IN1 and IN1B to generate a differential pair of intermediate signals M1 and M1B, which are fed to the second latch circuit 32 as input signals. The second latch circuit 32 is powered by an internal reference voltage VDDA (i.e., the driver power supply) and receives the differential pair of intermediate signals M1 and M1B to generate a differential pair of HV output signals OUT1 and OUT1B. In other embodiments, the latch-type level shift circuit 3 can further comprise a switch (not shown) selectively providing the internal reference voltage VDDA to the second latch circuit 32. The switch may be implemented with a MOS transistor. The latch-type level shift circuit 3 further comprises a charge pump circuit (not shown) boosting an external reference voltage (not shown) that is lower than the internal reference voltage (VDDA) to generate the independent reference voltage IRV.

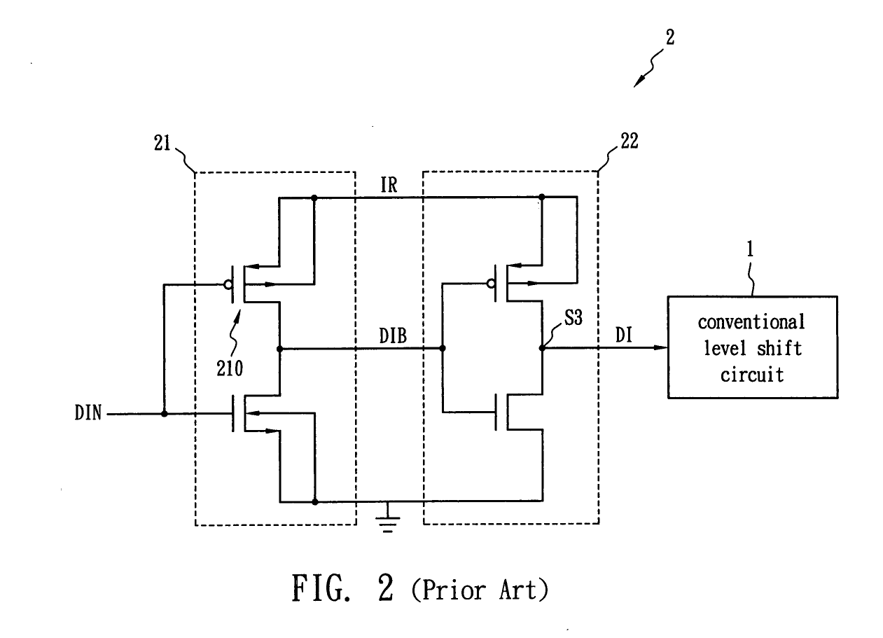

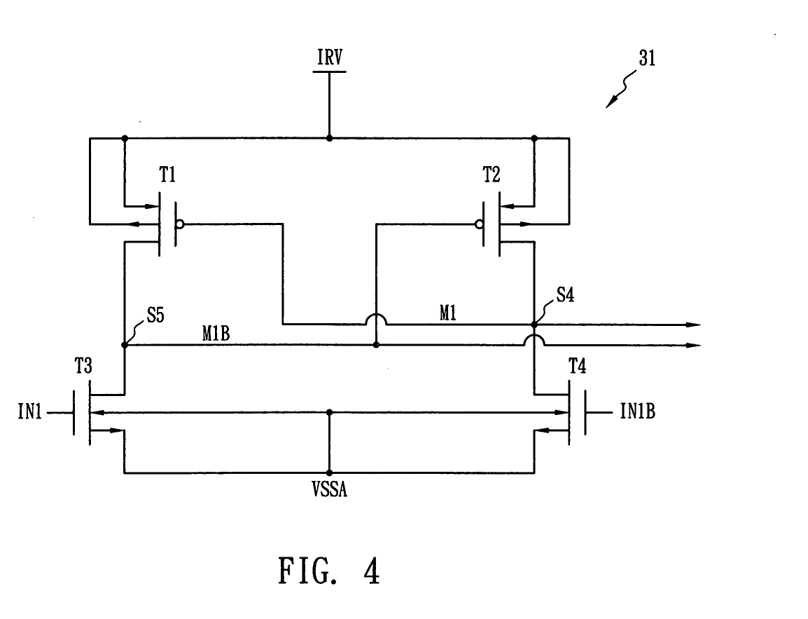

FIG. 4 shows an embodiment of the first latch circuit 31 used in the latch-type level shift circuit 3 of FIG. 3. The first latch circuit 31 comprises PMOS transistors T1 and T2, and NMOS transistors T3 and T4. All four transistors T1-T4 are LV transistors. The sources of the PMOS transistors T1 and T2 are electrically connected to the independent reference voltage IRV. The gates of the NMOS transistors T3 and T4 receive the differential pair of LV input signals IN1 and IN1B, respectively. The gate of the PMOS transistor T1 is electrically connected to the drain of the PMOS transistor T2 and provides the intermediate signal M1. The gate of the PMOS transistor T2 is electrically connected to the drain of the PMOS transistor T1 and provides the intermediate signal M1B. The intermediate signals M1 and M1B form the differential pair of intermediate signals. The sources of the NMOS transistors T3 and T4 are electrically connected to the driver ground VSSA. The drains of the NMOS transistors T3 and T4 are electrically connected to the drains of the PMOS transistors T1 and T2, respectively. Compared with FIG. 2, the first latch circuit 31 of FIG. 4 replaces the inverters 21 and 22 of the LV input stage 2 of FIG. 2.

The operation of the first latch circuit 31 is given below. Referring to FIG. 4, when the input signal IN1 is in high state (i.e., the input signal IN1B is in low state), the PMOS transistor T2 is turned on with the gate thereof at the driver ground VSSA through the conductive NMOS transistor T3, and the intermediate signal M1 at a node S4 is in high state with the voltage level of the independent reference voltage IRV. Also, the intermediate signal M1B at a node S5 is in low state at the driver ground VSSA. At the same time, the voltage level of the node S4 applied to the gate of the PMOS transistor T1 is equal to that of the independent reference voltage IRV applied to the source of the PMOS transistor T1, and thus, there is no leakage current resulting from the non-conductive PMOS transistor T1, even though the voltage level of independent reference voltage IRV is larger than that of the input signal IN1. When the input signal IN1 is in low state (i.e., the input signal IN1B is in high state), the PMOS transistor T1 is turned on with the gate thereof at the driver ground VSSA through the conductive NMOS transistor T4, and the intermediate signal M1 at the node S4 is in low state at the driver ground VSSA. Also, the intermediate signal M1B at the node S5 is in high state with the voltage level of the independent reference voltage IRV. At the same time, the voltage level of the node S5 applied to the gate of the PMOS transistor T2 is equal to that of the independent reference voltage IRV applied to the source of the PMOS transistor T2, and thus, there is no leakage current resulting from the non-conductive PMOS transistor T2. Accordingly, a higher voltage of the independent reference voltage IRV can be applied without current leakage. Compared with the conventional level shift circuit 1 combined with the LV input stage 2 of FIG. 2, there are no additional transistors or costs required in the first embodiment of the present invention.

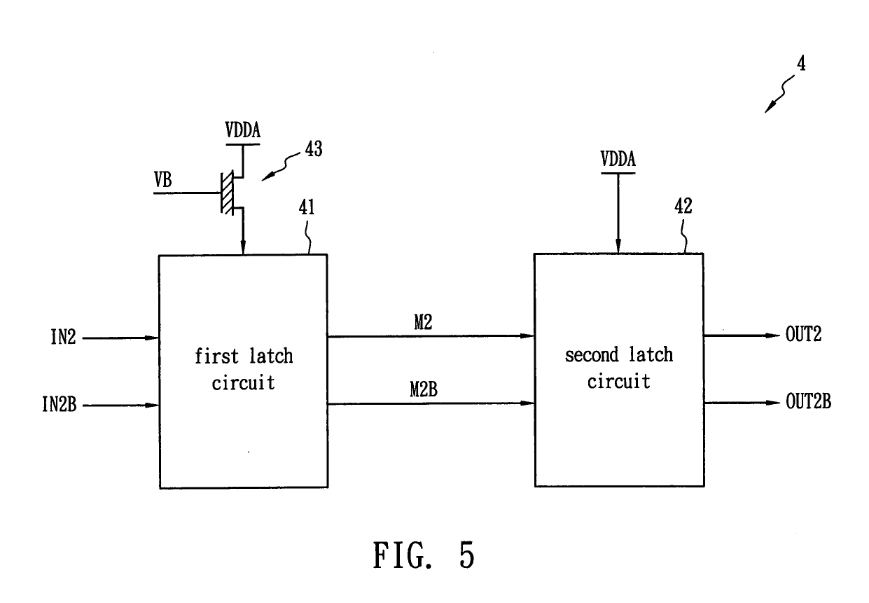

FIG. 5 shows a block diagram of the latch-type level shift circuit 4 in accordance with the second embodiment of the present invention. The latch-type level shift circuit 4 comprises a first latch circuit 41, a second latch circuit 42, and an HV NMOS transistor 43. In this embodiment, the second latch circuit 42 is equivalent to the conventional level shift circuit 1 of FIG. 1(a). The first latch circuit 41 receives a differential pair of LV input signals IN2 and IN2B to generate a differential pair of intermediate signals M2 and M2B, which are fed to the second latch circuit 42 as input signals. The second latch circuit 42 is powered by an internal reference voltage VDDA (i.e., the driver power supply) and receives the differential pair of intermediate signals M2 and M2B to generate a differential pair of HV output signals OUT2 and OUT2B. The HV NMOS transistor 43 has a drain receiving the internal reference voltage VDDA, a gate receiving a predetermined limit voltage VB, and a source powering the first latch circuit 41, so as to prevent the first latch circuit 41 from HV damages. The latch-type level shift circuit 4 can further comprise a switch (not shown) selectively providing the internal reference voltage VDDA to the second latch circuit 42. The switch may be implemented with a MOS transistor.

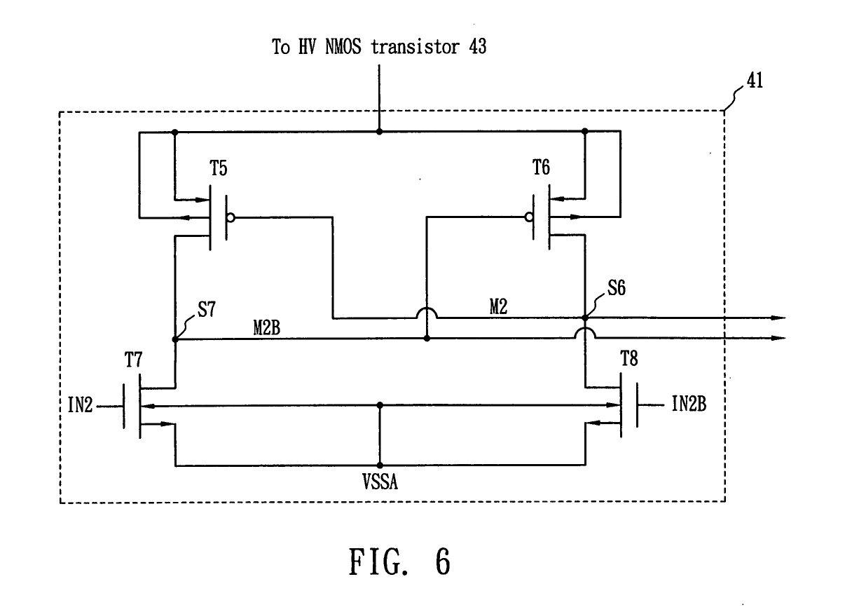

FIG. 6 shows an embodiment of the first latch circuit 41 used in the latch-type level shift circuit 4 of FIG. 5. The first latch circuit 41 comprises PMOS transistors T5 and T6, and NMOS transistors T7 and T8. All four transistors T5-T8 are LV transistors. The sources of the PMOS transistors T5 and T6 are electrically connected to the HV NMOS transistor 43. The gates of the NMOS transistors T7 and T8 receive the differential pair of LV input signals IN2 and IN2B, respectively. The gate of the PMOS transistor T5 is electrically connected to the drain of the PMOS transistor T6 and provides the intermediate signal M2. The gate of the PMOS transistor T6 is electrically connected to the drain of the PMOS transistor T5 and provides the intermediate signal M2B. The intermediate signals M2 and M2B form the differential pair of intermediate signals. The sources of the NMOS transistors T7 and T8 are electrically connected to the driver ground VSSA. The drains of the NMOS transistors T7 and T8 are electrically connected to the drains of the PMOS transistors T5 and T6, respectively. Compared with FIG. 2, the first latch circuit 41 (i.e., a high-level controlled level shift circuit which provides the driver power supply VDDA) of FIG. 6 replaces the inverters 21 and 22 of the LV input stage 2 of FIG. 2.

The operation of the first latch circuit 41 is given below. Referring to FIG. 6, when the input signal IN2 is in high state (i.e., the input signal IN2B is in low state), the PMOS transistor T6 is turned on with the gate thereof at the driver ground VSSA through the conductive NMOS transistor T7, and the intermediate signal M2 at a node S6 is in high state with the voltage level of the driver power supply VDDA with the HV NMOS transistor 43 being conductive. Also, the intermediate signal M2B at a node S7 is in low state at the driver ground VSSA. At the same time, the voltage level of the node S6 applied to the gate of the PMOS transistor T5 is equal to that of the driver power supply VDDA, through the conductive HV NMOS transistor 43, applied to the source of the PMOS transistor T5, and thus, there is no leakage current resulting from the non-conductive PMOS transistor T5, even though the voltage level of the driver power supply VDDA is larger than that of the input signal IN2 in high state. When the input signal IN2 is in low state (i.e., the input signal IN2B is in high state), the PMOS transistor T5 is turned on with the gate thereof at the driver ground VSSA through the conductive NMOS transistor T8, and the intermediate signal M2 at the node S6 is in low state at the driver ground VSSA. Also, the intermediate signal M2B at the node S7 is in high state with the voltage level of the driver power supply VDDA. At the same time, the voltage level of the node S7 applied to the gate of the PMOS transistor T6 is equal to that of the driver power supply VDDA, through the conductive HV NMOS transistor 43, applied to the source of the PMOS transistor T6, and thus, there is no leakage current resulting from the non-conductive PMOS transistor T6. Accordingly, a higher voltage level of the driver power supply VDDA can be applied without current leakage. In addition, referring to FIGS. 5 and 6, the voltage level of the input signal IN2 or IN2B in high state can be determined by the predetermined limit voltage VB.

According to the above embodiments, by replacing the inverters of the conventional level shift circuit with the first latch circuit, the first embodiment of the present invention can sustain a higher internal power without a leakage current; by replacing the inverters of the conventional level shift circuit with the high-level controlled level shift circuit, the second embodiment of the present invention exhibits no leakage current and can omit the use of a charge pump circuit. Therefore, the expected objectives of the present invention can be achieved.

The above-described embodiments of the present invention are intended to be illustrative only. Numerous alternative embodiments may be devised by those skilled in the art without departing from the scope of the following claims.

What is claimed is:

1. A latch-type level shift circuit, comprising:
a first latch circuit powered by an independent reference voltage, receiving a differential pair of low-voltage (LV) input signals to generate a differential pair of intermediate signals; and
a second latch circuit powered by an internal reference voltage, receiving the differential pair of intermediate signals to generate a differential pair of high-voltage(HV) output signals.

2. The latch-type level shift circuit of claim 1, further comprising a switch circuit selectively providing the internal reference voltage to the second latch circuit.

3. The latch-type level shift circuit of claim 1, further comprising a charge pump circuit boosting an external reference voltage that is lower than the internal reference voltage to generate the independent reference voltage.

4. The latch-type level shift circuit of claim 1, wherein the first latch circuit comprises:
a first PMOS transistor;
a second PMOS transistor having a source electrically connected to a source of the first PMOS transistor and the independent reference voltage, a gate electrically connected to a drain of the first PMOS transistor and generating one of the differential pair of intermediate signals, and a drain electrically connected to a gate of the first PMOS transistor and generating the other of the differential pair of intermediate signals;
a first NMOS transistor having a gate receiving one of the differential pair of LV input signals, a drain electrically connected to the drain of the first PMOS transistor, and a source electrically connected to a ground; and
a second NMOS transistor having a gate receiving the other of the differential pair of LV input signals, a drain electrically connected to the drain of the second PMOS transistor, and a source electrically connected to the ground.

5. The latch-type level shift circuit of claim 1, wherein the second latch circuit comprises:
a first HV PMOS transistor having a source electrically connected to the internal reference voltage;
a second HV PMOS transistor having a source electrically connected to the internal reference voltage, a gate electrically connected to a drain of the first HV PMOS transistor and generating one of the differential pair of HV output signals, and a drain electrically connected to a gate of the first HV PMOS transistor and generating the other of the differential pair of HV output signals;
a first HV NMOS transistor having a drain electrically connected to the drain of the first HV PMOS transistor, a gate receiving one of the differential pair of intermediate signals, and a source electrically connected to a ground; and
a second HV NMOS transistor having a drain electrically connected to the drain of the second HV PMOS transistor, a gate receiving the other of the differential pair of intermediate signals, and a source electrically connected to the ground.

6. A latch-type level shift circuit, comprising:
a first latch circuit receiving a differential pair of LV input signals to generate a differential pair of intermediate signals;
a second latch circuit powered by an internal reference voltage, receiving the differential pair of intermediate signals to generate a differential pair of HV output signals; and
an HV MOS transistor having a drain receiving the internal reference voltage, a gate receiving a predetermined limit voltage, and a source powering the first latch circuit, so as to prevent the first latch circuit from HV damages.

7. The latch-type level shift circuit of claim 6, further comprising an HV switch circuit selectively providing the internal reference voltage to the second latch circuit.

8. The latch-type level shift circuit of claim 6, wherein the first latch circuit comprises:
a first PMOS transistor;
a second PMOS transistor having a source electrically connected to a source of the first PMOS transistor and the source of the HV NMOS transistor, a gate electrically connected to a drain of the first PMOS transistor and generating one of the differential pair of intermediate signals, and a drain electrically connected to a gate of the first PMOS transistor and generating the other of the differential pair of intermediate signals;
a first NMOS transistor having a gate receiving one of the differential pair of LV input signals, a drain electrically connected to the drain of the first PMOS transistor, and a source electrically connected to a ground; and
a second NMOS transistor having a gate receiving the other of the differential pair of LV input signals, a drain electrically connected to the drain of the second PMOS transistor, and a source electrically connected to the ground.

9. The latch-type level shift circuit of claim 6, wherein the second latch circuit comprises:
a first HV PMOS transistor having a source electrically connected to the internal reference voltage;
a second HV PMOS transistor having a source electrically connected to the internal reference voltage, a gate electrically connected to a drain of the first HV PMOS transistor and generating one of the differential pair of HV output signals, and a drain electrically connected to a gate of the first HV PMOS transistor and generating the other of the differential pair of HV output signals;
a first HV NMOS transistor having a drain electrically connected to the drain of the first HV PMOS transistor, a gate receiving one of the differential pair of intermediate signals, and a source electrically connected to a ground; and
a second HV NMOS transistor having a drain electrically connected to the drain of the second HV PMOS transistor, a gate receiving the other of the differential pair of intermediate signals, and a source electrically connected to the ground.
